(19) United States
(12) Patent Application Publication
(10) Pub. No.: US 2026/0267521 A1
(43) Pub. Date: Sep. 10, 2026

(54) MEMORY SYSTEM AND STORAGE DEVICE

(71) Applicant: Kioxia Corporation, Tokyo (JP)

(72) Inventor: Yosuke KOBAYASHI, Seoul (KR)

(73) Assignee: Kioxia Corporation, Tokyo (JP)

(21) Appl. No.: 19/235,238

(22) Filed: Jun. 11, 2025

(30) Foreign Application Priority Data
Mar. 7, 2025 (JP) 2025-036415

(51) Int. Cl. G06F 3/06; G11C 11/16

(52) U.S. Cl. CPC G06F 3/0614; G06F 3/0659; G06F 3/0673; G11C 11/1673; G11C 11/1675

(57) ABSTRACT

According to one embodiment, a memory system includes: a storage device including a plurality of memory cells each having a variable resistance element and a switching element electrically coupled in series, a write circuit, and a read circuit; and an external device, wherein the memory system is configured to execute seasoning processing including first processing and second processing, in the first processing, the read circuit executes a plurality of seasoning read operations, and the external device generates first fail data storing whether data read has failed not less than once in the plurality of seasoning read operations, and in the second processing, the write circuit executes selective seasoning processing based on the first fail data.

### CROSS-REFERENCE TO RELATED APPLICATIONS

This application is based upon and claims the benefit of priority from Japanese Patent Application No. 2025-036415, filed Mar. 7, 2025, the entire contents of which are incorporated herein by reference.

### FIELD

Embodiments described herein relate generally to a memory system and a storage device.

### BACKGROUND

There are known a storage device that stores different pieces of information in accordance with the resistance state and a memory system including the storage device.

### BRIEF DESCRIPTION OF THE DRAWINGS

FIG. 1 is a block diagram for explaining the arrangement of a memory system according to an embodiment.

FIG. 2 is a circuit diagram for explaining the arrangement of a memory cell array according to the embodiment.

FIG. 3 is a plan view for explaining the arrangement of the memory cell array according to the embodiment.

FIG. 4 is a sectional view along line IV-IV in FIG. 3, showing the sectional structure of the memory cell array according to the embodiment.

FIG. 5 is a sectional view for explaining the arrangement of a magnetoresistance effect element according to the embodiment.

FIG. 6 is a view showing the characteristic of a switching element according to the embodiment.

FIG. 7 is a block diagram for explaining the arrangement of the memory controller of the memory system according to the embodiment.

FIG. 8 is a view for explaining various types of data in the memory system according to the embodiment.

FIG. 9 is a flowchart for explaining seasoning processing in the memory system according to the embodiment.

FIG. 10 is a view for explaining the updating of fail data in seasoning processing in the memory system according to the embodiment.

FIG. 11 is a view for explaining data used for a modify write operation in seasoning processing in the memory system according to the embodiment.

FIG. 12 is a block diagram for explaining the arrangement of a storage device according to a modification.

### DETAILED DESCRIPTION

In general, according to one embodiment, a memory system includes: a storage device including a first interconnect and a second interconnect, a plurality of memory cells each having a variable resistance element and a switching element electrically coupled to the first interconnect and the second interconnect and coupled in series, a write circuit configured to write data in the plurality of memory cells, and a read circuit configured to read data written in the plurality of memory cells; and an external device, wherein the memory system is configured to execute seasoning processing including first processing and second processing, in the first processing, the read circuit executes a plurality of seasoning read operations each configured to read data from the plurality of memory cells, and the external device generates first fail data storing whether in each of the plurality of memory cells, data read has failed not less than once in the plurality of seasoning read operations, and in the second processing, the write circuit executes selective seasoning processing a plurality of times with respect to a target memory cell, of the plurality of memory cells, which is determined based on the first fail data.

An embodiment will be described below with reference to the accompanying drawings. In the following description, the same reference numerals denote constituent elements having the same functions and arrangements. If a plurality of constituent elements having the same reference numerals are discriminated from each other, suffixes are attached to the same reference numerals. If there is no need to discriminate such constituent elements, only the same reference numerals are attached to the constituent elements without any suffixes. In this case, the suffixes include, in addition to subscripts and superscripts, for example, lowercase alphabets and indices indicating arrays which are attached to the ends of reference numerals.

### 1. Embodiment

### 1.1 Arrangement

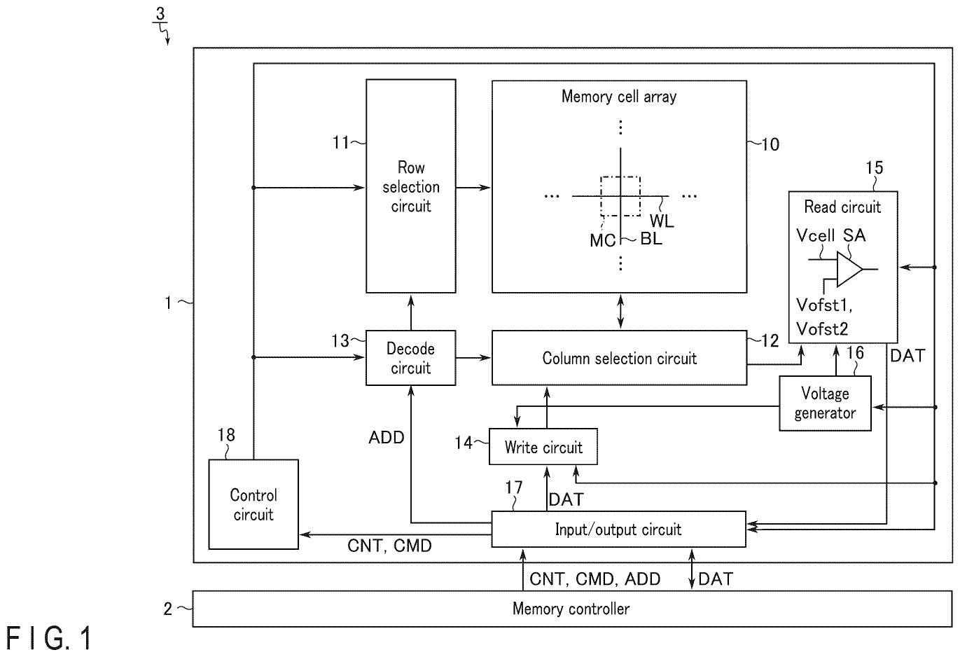

An example of the arrangement of a memory system according to an embodiment will be described with reference to FIG. 1. FIG. 1 is a block diagram for explaining the arrangement of the memory system according to the embodiment.

A memory system 3 includes a storage device 1 and a memory controller 2. The memory controller 2 is an external device that controls the storage device 1.

The storage device 1 stores data by using variable resistance elements. More specifically, the storage device 1 according to the embodiment is, for example, a magnetic storage device (MRAM: Magnetoresistive Random Access Memory) of a perpendicular magnetization system using an element having a magnetoresistance effect based on MTJ (Magnetic Tunnel Junction) as a variable resistance element. In the following description, the variable resistance element will be simply referred to as an MTJ element. In addition, in the following description, the storage device 1 is a magnetic storage device including an MTJ element as a variable resistance element. However, this is not exhaustive. The storage device 1 may include, as a variable resistance element, an element different from an MTJ element. The storage device 1 may be, for example, a ReRAM (Resistive Random Access Memory) or PCRAM (Phase-change Random Access Memory).

### 1.1.1 Storage Device

The arrangement of the storage device 1 will continuously be described with reference to FIG. 1.

The storage device 1 includes a memory cell array 10, a row selection circuit 11, a column selection circuit 12, a decode circuit 13, a write circuit 14, a read circuit 15, a voltage generator 16, an input/output circuit 17, and a control circuit 18.

The memory cell array 10 includes a plurality of memory cells MC each associated with a combination of a row and a column. The memory cells MC on the same row are coupled to the same word line WL. The memory cells MC on the same column are coupled to the same bit line BL.

The row selection circuit 11 is coupled to the memory cell array 10 via the word line WL. The row selection circuit 11 receives the decoding result (row address) of an address ADD from the decode circuit 13. The row selection circuit 11 sets the word line WL corresponding to the row based on the decoding result of the address ADD in a selected state. The word line WL set in a selected state will be referred to as the selected word line WL hereinafter. The word lines WL other than the selected word line WL will be referred to as the non-selected word lines WL.

The column selection circuit 12 is coupled to the memory cell array 10 via the bit line BL. The column selection circuit 12 receives the decoding result (column address) of the address ADD from the decode circuit 13. The column selection circuit 12 sets the bit line BL corresponding to the column based on the decoding result of the address ADD in a selected state. The bit line BL set in a selected state will be referred to as the selected bit line BL hereinafter. The bit lines BL other than the bit line BL set in a selected state will be referred to as the non-selected bit lines BL.

The decode circuit 13 decodes the address ADD from the input/output circuit 17. The decode circuit 13 supplies the decoding result of the address ADD to the row selection circuit 11 and the column selection circuit 12. The address ADD includes the selected column address and row address.

The write circuit 14 writes data to the memory cell MC. The write circuit 14 includes, for example, a write driver (not shown).

The read circuit 15 reads data from the memory cell MC. The read circuit 15 includes, for example, a plurality of sense amplifiers SA corresponding to the plurality of word lines WL.

Each sense amplifier SA compares a read voltage Vcell1 of each memory cell MC corresponding to the sense amplifier SA with a reference voltage Vofst1 in a read operation. In a read operation of each memory cell MC, for example, the voltage of the bit line BL corresponding to the memory cell MC is defined as a voltage VSS of the bit line BL corresponding to the memory cell MC, and a constant current is applied to the memory cell MC. The voltage VSS is, for example, 0 V. The read voltage Vcell1 is the voltage of the word line WL corresponding to the memory cell MC when the constant current is applied to the memory cell MC. For example, the sense amplifier SA senses the data of each memory cell MC based on the comparison between the read voltage Vcell1 and the reference voltage Vofst1.

In seasoning processing, each sense amplifier SA compares a read voltage Vcell2 of each memory cell MC corresponding to the sense amplifier SA with a reference voltage Vofst2. The reference voltage Vofst2 is a voltage different from the reference voltage Vofst1. Seasoning processing is executed to, for example, stabilize each memory cell MC and adjust the operating voltage of each memory cell MC before the use of the storage device 1. In seasoning processing, a combination of a plurality of seasoning read operations and a plurality of write operations (a plurality of modify write operations) based on the plurality of seasoning read operations is repeatedly executed. In each seasoning read operation, a constant current is applied to the target memory cell MC as in the read operation. The read voltage Vcell2 is the voltage of the word line WL corresponding to the above memory cell MC upon application of a constant current. In each seasoning read operation, each sense amplifier SA compares the read voltage Vcell2 of each memory cell MC corresponding to the sense amplifier SA with the reference voltage Vofst2. The sense amplifier SA senses the data of each memory cell MC based on the comparison between the read voltage Vcell2 and the reference voltage Vofst2. The setting of the reference voltage Vofst2 and seasoning processing will be described in more detail later.

The voltage generator 16 generates voltages for various types of operations of the memory cell array 10. For example, the voltage generator 16 generates various types of voltages required for a write operation and outputs the voltages to the write circuit 14. In addition, for example, the voltage generator 16 generates various types of voltages required for a read operation and a seasoning read operation and outputs the voltages to the read circuit 15.

The input/output circuit 17 is a circuit that inputs and outputs data and signals. The input/output circuit 17 receives a control signal CNT, a command CMD, the address ADD, and data (write data) DAT from the memory controller 2. The input/output circuit 17 transfers the address ADD from the memory controller 2 to the decode circuit 13. The input/output circuit 17 transfers the control signal CNT and the command CMD from the memory controller 2 to the control circuit 18. The input/output circuit 17 transfers the data DAT from the memory controller 2 to the write circuit 14.

The input/output circuit 17 transmits, for example, the data (read data) DAT to the memory controller 2. The input/output circuit 17 outputs the data DAT transferred from the read circuit 15 to the memory controller 2.

The control circuit 18 controls the operations of the row selection circuit 11, the column selection circuit 12, the decode circuit 13, the write circuit 14, the read circuit 15, the voltage generator 16, and the input/output circuit 17 in the storage device 1 based on the control signal CNT and the command CMD.

### 1.1.2 Arrangement of Memory Cell Array

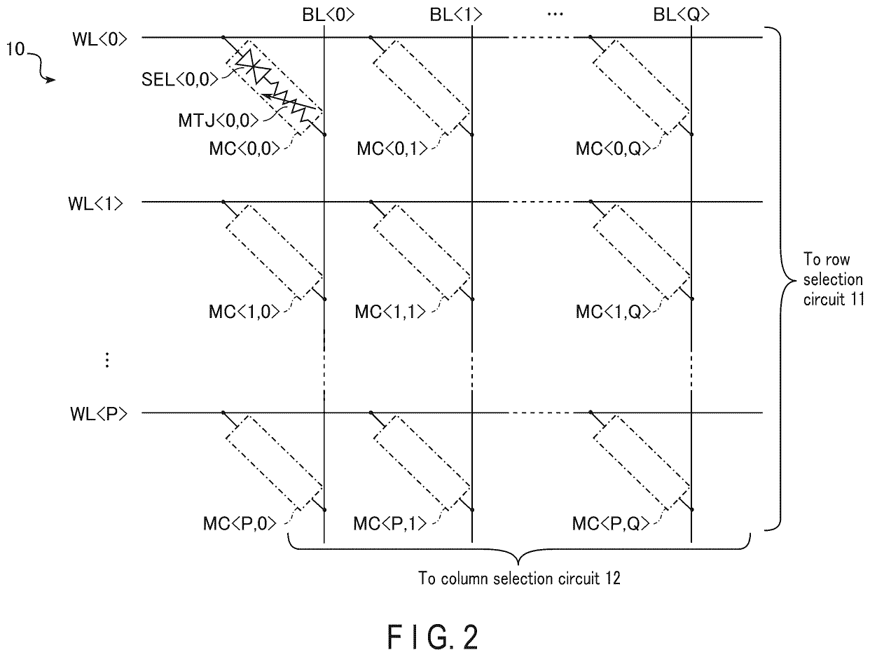

An example of the arrangement of the memory cell array 10 of the storage device 1 will be described next with reference to FIG. 2. FIG. 2 is a circuit diagram for explaining the arrangement of the memory cell array according to the embodiment. Referring to FIG. 2, the word lines WL are classified according to suffixes including indices “<>”.

The memory cells MC are arranged in a matrix pattern in the memory cell array 10. Each memory cell MC is associated with a set of one of the plurality of bit lines BL (BL<0>, BL<1>, . . . , BL<Q>) and one of the plurality of word lines WL (WL<0>, WL<1>, . . . , WL<P>) (P and Q are natural numbers). That is, the memory cell MC<i, j> (0≤i≤P, 0≤j≤Q where i and j are natural numbers) is coupled between the word line WL<i> and the bit line BL<j>.

The memory cell MC<i, j> includes a switching element SEL<i, j> and a magnetoresistance effect element MTJ<i, j> connected in series.

The switching element SEL is a two-terminal switching element. A two-terminal switching element differs from a three-terminal switching element such as a transistor in that it does not include the third terminal. The switching element SEL can switch between a high-resistance state and a low-resistance state depending on the voltage applied between the two terminals. The high-resistance state is, for example, an OFF state in which the switching element is in an electrically nonconductive state. The low-resistance state is an ON state in which the switching element is in an electrically conductive state. The switching element SEL switches whether to make a current flow or shut off the current according to the magnitude of the voltage applied to the corresponding memory cell MC regardless of the polarity of the voltage applied between the two terminals (regardless of the flowing direction of a current). More specific characteristics of the switching element SEL will be described later.

The magnetoresistance effect element MTJ can switch the resistance state between a low-resistance state and a high-resistance state based on the current controlled by the switching element SEL. The magnetoresistance effect element MTJ can write data based on a change in the resistance state and functions as a readable memory element that nonvolatilely stores the written data.

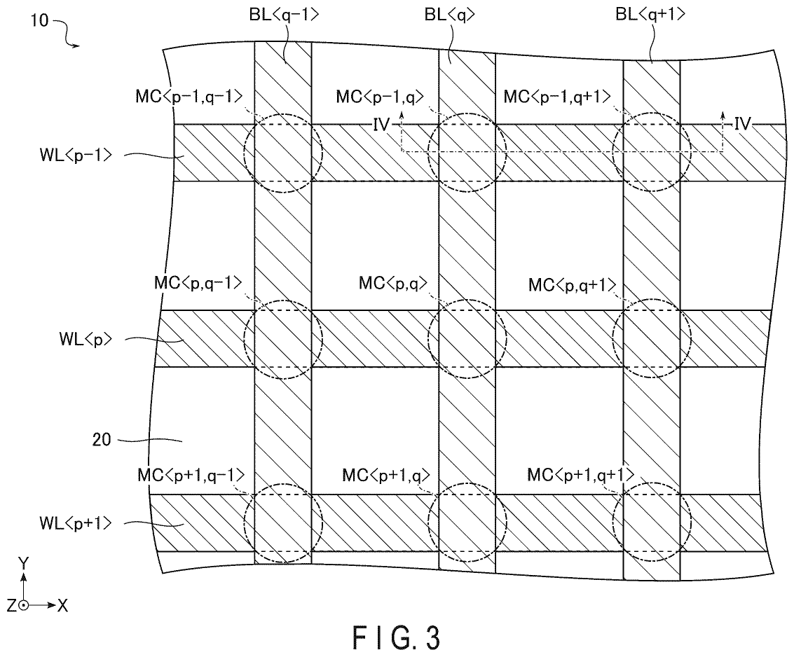

An example of the placement of the memory cells MC in the memory cell array 10 will be described next with reference to FIG. 3. FIG. 3 is a plan view for explaining the arrangement of a memory cell array according to the embodiment. FIG. 3 shows the plurality of memory cells MC provided between three word lines WL<p−1>, WL<p>, and WL<p+1> and three bit lines BL<q−1>, BL<q>, and BL<q+1> of the memory cell array 10 (1≤p≤P−1 and 1≤q≤Q−1 where p and q are natural numbers). For the sake of descriptive convenience, the illustration of an interlayer dielectric film is omitted in FIG. 3.

The memory cell array 10 is provided above a semiconductor substrate 30. In the following description, a plane parallel to a surface of the semiconductor substrate 30 is defined as an XY plane, and a direction perpendicular to the XY plane is defined as a Z direction. In the XY plane, one of a pair of two directions orthogonal to each other is defined as an X direction or Y direction.

The plurality of memory cells MC are provided between the word lines WL and the bit lines BL. In the example shown in FIG. 3, the word lines WL are provided below the memory cells MC, and the bit lines BL are provided above the memory cells MC. However, this is not exhaustive. The vertical positional relationship between the word lines WL and the bit lines BL may be reversed.

The plurality of word lines WL are arranged side by side along the Y direction. Each of the plurality of word lines WL extends along the X direction. The plurality of bit lines BL are arranged side by side along the X direction. Each of the plurality of bit lines BL extends along the Y direction. The distance between the two word lines WL can be set to be, for example, substantially equal to the distance between the two bit lines BL. One memory cell MC is provided at the intersection between one bit line BL and one word line WL.

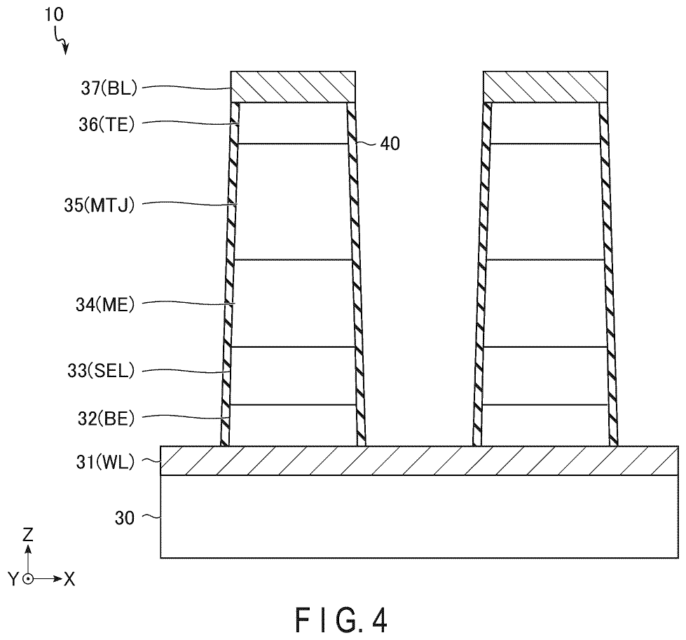

An example of the sectional structure of the memory cell array 10 will be described next with reference to FIG. 4. FIG. 4 is a sectional view along line IV-IV in FIG. 3, showing the sectional structure of the memory cell array according to the embodiment.

The memory cell array 10 is provided above the semiconductor substrate 30.

The memory cell array 10 includes a plurality of conductors 31, a plurality of electrodes 32, a plurality of elements 33, a plurality of electrodes 34, a plurality of elements 35, a plurality of electrodes 36, and a plurality of conductors 37.

The plurality of conductors 31 are provided on the upper surface of the semiconductor substrate 30. Each of the plurality of conductors 31 extends along the X direction. As shown in FIG. 3, the plurality of conductors 31 are arranged side by side along the Y direction in a region (not shown in FIG. 4). Each of the plurality of conductors 31 has conductivity and functions as the word line WL. Each of the plurality of conductors 31 is insulated. The case where the plurality of conductors 31 are provided on the semiconductor substrate 30 has been described with reference to FIG. 4. However, the present invention is not limited to this. For example, a layer different from the conductor 31 and the semiconductor substrate 30 may be provided between them.

The plurality of electrodes 32 are provided on the upper surface of each of the plurality of conductors 31. The plurality of electrodes 32 provided on the upper surface of the same conductor 31 are arranged side by side in the X direction. Referring to FIG. 4, of the plurality of electrodes 32, the two electrodes 32 are provided on each of the two conductors 31. Each of the plurality of electrodes 32 has, for example, a circular shape along an XY section. Each of the plurality of electrodes 32 is used as a lower electrode BE.

Each of the plurality of elements 33 is provided on the upper surface of a corresponding one of the plurality of electrodes 32. Each of the plurality of elements 33 has, for example, a circular shape along an XY section. Each of the plurality of elements 33 is used as the switching element SEL. The plurality of elements 33 each contain an insulator and a dopant ion-implanted into the insulator. The insulator contains, for example, an oxide and SiO₂ or a material substantially composed of SiO₂. The dopant includes, for example, arsenic (As) and germanium (Ge). The expression “substantially composed (or formed) of” or a similar expression means that the constituent element “substantially composed” is allowed to contain an unintentional impurity.

Each of the plurality of electrodes 34 is provided on the upper surface of a corresponding one of the plurality of elements 33. Each of the plurality of electrodes 34 has, for example, a circular shape along an XY section. Each of the plurality of electrodes 34 is used as an intermediate electrode ME.

Each of the plurality of elements 35 is provided on the upper surface of a corresponding one of the plurality of electrodes 34. Each of the plurality of elements 35 has, for example, a circular shape along an XY section. Each of the plurality of elements 35 functions as the magnetoresistance effect element MTJ. The arrangement of the elements 35 will be described in detail later.

Each of the plurality of electrodes 36 is provided on the upper surface of a corresponding one of the plurality of elements 35. Each of the plurality of electrodes 36 has, for example, a circular shape along an XY section. Each of the plurality of electrodes 36 is used as an upper electrode TE.

As described with reference to the above arrangement, a plurality of structures each including the electrodes 32, 34, and 36 and the elements 33 and 35 are also referred to as a plurality of multilayer structures. Each of the plurality of multilayer structures corresponds to each of the plurality of memory cells MC. In addition, with the above arrangement, each of the plurality of memory cells MC has, for example, a circular shape along an XY section.

A side surface of each of the plurality of multilayer structures is provided with a side wall insulator 40 so as to cover the side surface. The side wall insulator 40 is, for example, provided up to a height equal to the level of the upper surface of the electrode 36. The side wall insulator 40 may be composed of a plurality of insulator materials.

The plurality of conductors 37 are arranged side by side along the X direction. Although not shown, each of the plurality of conductors 37 extends along the Y direction so as to come into contact with the upper surface of a corresponding one of the plurality of electrodes 36 arranged side by side along the X direction. Each of the plurality of conductors 37 has conductivity and functions as the bit line BL.

### 1.1.3 Magnetoresistance Effect Element

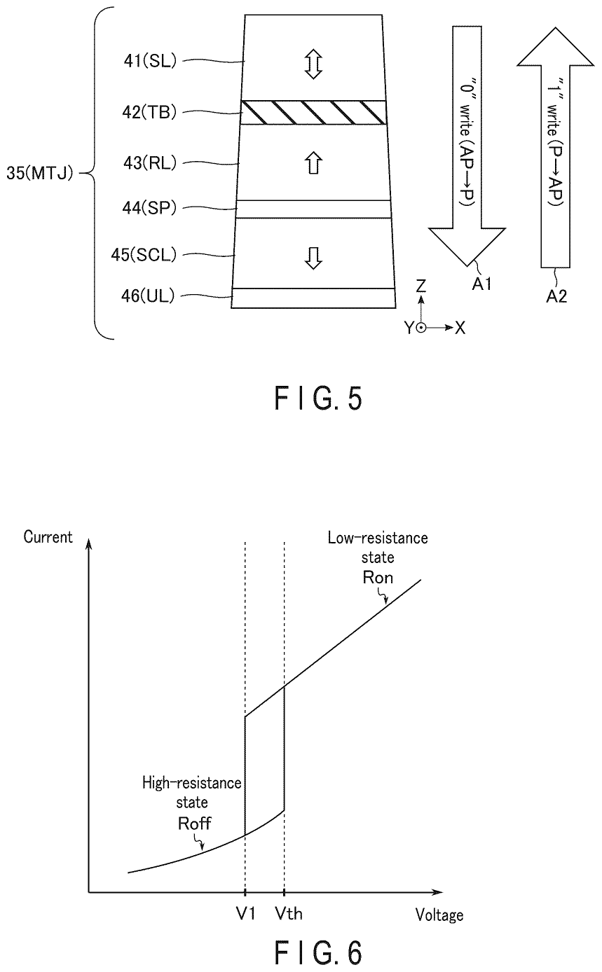

An example of the arrangement of the magnetoresistance effect element MTJ of the storage device 1 according to the embodiment will be described next with reference to FIG. 5. FIG. 5 is a sectional view for explaining the arrangement of the magnetoresistance effect element according to the embodiment.

The element 35 used as the magnetoresistance effect element MTJ includes a ferromagnet 41, a nonmagnet 42, a ferromagnet 43, a nonmagnet 44, a ferromagnet 45, and a nonmagnet 46.

The ferromagnet 41 is a conductive film having ferromagnetism. The ferromagnet 41 has a magnetization easy axis direction in a direction (Z direction) perpendicular to the film surface. The ferromagnet 41 contains iron (Fe). The ferromagnet 41 can also contain an element selected from the group consisting of cobalt (Co) and nickel (Ni). In addition, the ferromagnet 41 can contain boron (B). More specifically, for example, the ferromagnet 41 contains cobalt-iron-boron (CoFeB), iron boride (FeB), or cobalt boride (CoB). The ferromagnet 41 is used as a storage layer SL.

The nonmagnet 42 is provided on the lower surface of the ferromagnet 41. The nonmagnet 42 is an insulating film having nonmagnetism. The nonmagnet 42 is used as a tunnel barrier layer TB. The nonmagnet 42 is provided between the ferromagnet 41 and the ferromagnet 43 and forms a magnetic tunnel junction together with the ferromagnet 41 and the ferromagnet 43. In addition, the nonmagnet 42 functions as a seed material serving as a nucleus for growing a crystalline film from an interface with the ferromagnet 41 in the crystallization processing of the ferromagnet 41. The nonmagnet 42 has an NaCl crystal structure in which the film surface is oriented in the (001) plane. The nonmagnet 42 contains, for example, magnesium oxide (MgO).

The ferromagnet 43 is provided on the lower surface of the nonmagnet 42. The ferromagnet 43 is a conductive film having ferromagnetism. The ferromagnet 43 is used as a reference layer RL. The ferromagnet 43 has a magnetization easy axis direction in a direction (Z direction) perpendicular to the film surface. The magnetization direction of the ferromagnet 43 is fixed. In the example shown in FIG. 3, the magnetization direction of the ferromagnet 43 is a direction from the ferromagnet 43 to the ferromagnet 41. Note that “the magnetization direction is fixed” means that the magnetization direction is not changed by a torque large enough to invert the magnetization direction of the ferromagnet 41. The ferromagnet 43 contains, for example, at least one compound selected from the group consisting of cobalt platinum (CoPt), cobalt nickel (CoNi), and cobalt palladium (CoPd).

The nonmagnet 44 is provided on the lower surface of the ferromagnet 43. The nonmagnet 44 is a conductive film having nonmagnetism. The nonmagnet 44 is used as a spacer layer SP. The nonmagnet 44 contains, for example, at least one element selected from the group consisting of ruthenium (Ru), osmium (Os), rhodium (Rh), iridium (Ir), vanadium (V), and chromium (Cr).

The ferromagnet 45 is provided on the lower surface of the nonmagnet 44. The ferromagnet 45 is a conductive film having ferromagnetism. The ferromagnet 45 is used as a shift cancelling layer SCL. The ferromagnet 45 has a magnetization easy axis direction in a direction (Z direction) perpendicular to the film surface. The magnetization direction of the ferromagnet 45 is fixed. In the example shown in FIG. 3, the magnetization direction of the ferromagnet 45 is a direction from the ferromagnet 43 to the ferromagnet 45. The ferromagnet 45 contains, for example, at least one compound selected from the group consisting of cobalt platinum (CoPt), cobalt nickel (CoNi), and cobalt palladium (CoPd).

The ferromagnet 43 and the ferromagnet 45 are anti-ferromagnetically coupled to each other via the nonmagnet 44. That is, the ferromagnet 43 and the ferromagnet 45 are coupled so as to have anti-parallel magnetization directions. Such coupled structure of the ferromagnet 43, the nonmagnet 44, and the ferromagnet 45 will be referred to as an SAF (Synthetic Anti-Ferromagnetic) structure. With the SAF structure, the ferromagnet 45 can cancel out the influence of the leakage field of the ferromagnet 43 on the magnetization direction of the ferromagnet 41. This makes it possible to reduce the substantial leakage field of the ferromagnet 45.

The nonmagnet 46 is provided on the lower surface of the ferromagnet 45. The nonmagnet 46 is a conductive film having nonmagnetism. The nonmagnet 46 is used as an under layer UL. A nonmagnet 38 contains, for example, at least one element selected from the group consisting of zirconium (Zr), hafnium (Hf), tungsten (W), chromium (Cr), molybdenum (Mo), niobium (Nb), titanium (Ti), tantalum (Ta), vanadium (V), ruthenium (Ru), and platinum (Pt).

The magnetoresistance effect element MTJ can assume either a low-resistance state or a high-resistance state depending on whether the relative relationship between the magnetization directions of the storage layer SL and the reference layer RL is parallel or anti-parallel. In this embodiment, a write current is made to flow in the magnetoresistance effect element MTJ to control the magnetization direction of the storage layer SL with respect to the magnetization direction of the reference layer RL. More specifically, the embodiment adopts a write scheme using the spin transfer torque generated by making a current flow in the magnetoresistance effect element MTJ.

If a write current Ic0 having a certain magnitude is made to flow in a direction from the storage layer SL to the reference layer RL (the direction indicated by an arrow A1 in FIG. 3) in the magnetoresistance effect element MTJ, the relative relationship between the magnetization directions of the storage layer SL and the reference layer RL becomes parallel. In this parallel state, the resistance value of the magnetoresistance effect element MTJ becomes lowest, and the magnetoresistance effect element MTJ is set in a low-resistance state. This low-resistance state is referred to as a “P (Parallel) state” and defined as, for example, a data “0” state.

If a current Ic1 larger than the write current Ic0 is made to flow in a direction from the reference layer RL to the storage layer SL (the direction indicated by an arrow A2 in FIG. 3) in the magnetoresistance effect element MTJ, the relative relationship between the magnetization directions of the storage layer SL and the reference layer RL becomes anti-parallel. In this anti-parallel state, the resistance value of the magnetoresistance effect element MTJ becomes highest, and the magnetoresistance effect element MTJ is set in a high-resistance state. This high-resistance state is referred to as an “AP (Anti-Parallel) state” and defined as, for example, a data “1” state.

Note that the manner of defining data “1” and data “0” is not limited to the above example. For example, a P state may be defined as data “1”, and an AP state may be defined as data “0”.

### 1.1.4 Characteristic of Switching Element

An example of the characteristic of the switching element SEL will be described next with reference to FIG. 6. FIG. 6 is a graph showing the characteristic of the switching element according to the embodiment. Referring to FIG. 6, the ordinate and the abscissa respectively indicate the current flowing in the switching element SEL and the voltage between the terminals of the switching element SEL.

When the voltage between the terminals of the switching element SEL in a high-resistance state is raised, as indicated by the solid line in FIG. 6, the resistance between the terminals of the switching element SEL (to be simply referred to as the resistance of the switching element SEL hereinafter) rapidly decreases from a resistance Roff to a resistance Ron (Roff>Ron) at a threshold voltage Vth of the switching element SEL. That is, the switching element SEL changes from a high-resistance state to a low-resistance state. This rapidly increases the current flowing in the switching element SEL. In contrast to this, when the voltage between the terminals of the switching element SEL in a low-resistance state is lowered, for example, the resistance value rapidly increases from the resistance Ron to the resistance Roff at a voltage V1 lower than the threshold voltage Vth. That is, the switching element SEL changes from a low-resistance state to a high-resistance state. This rapidly decreases the current flowing in the switching element SEL.

The storage device 1 executes a write operation and a read operation after the state of the switching element SEL changes from the initial state to a used state due to forming processing and seasoning processing.

In forming processing, the write circuit 14 increases the voltage between the terminals of the switching element SEL in the initial state to make a write current flow. This forms a conductive filament (electrical conduction path) in the switching element SEL. The high-resistance state of the switching element SEL in the initial state has a resistance Ri higher than the resistance Roff of the high-resistance state of the switching element SEL in a used state (Ri>Roff).

In the seasoning processing, as described above, the storage device 1 repeatedly executes a combination of a plurality of seasoning read operations and a plurality of modify write operations. In each modify write operation, the write circuit 14 increases the voltage between the terminals of the switching element SEL to make a write current flow as in the forming processing. Making the write current flow in this manner further stabilizes the conductive filament formed in the forming processing. This makes it possible to make the operating voltage of the switching element SEL fall within an intended voltage range. In addition, decreasing the read voltage Vcell1 in executing a read operation can make the read voltage Vcell1 fall within an intended voltage range.

The arrangement according to the above embodiment has exemplified the case where the memory system 3 includes the memory controller 2. However, this is not exhaustive. The memory system 3 may include an external device such as a tester instead of the memory controller 2. In this case, the external device such as a tester includes a first comparison circuit 21, a built-in memory 22, a second comparison circuit 23, and a counter 24.

### 1.1.5 Memory Controller

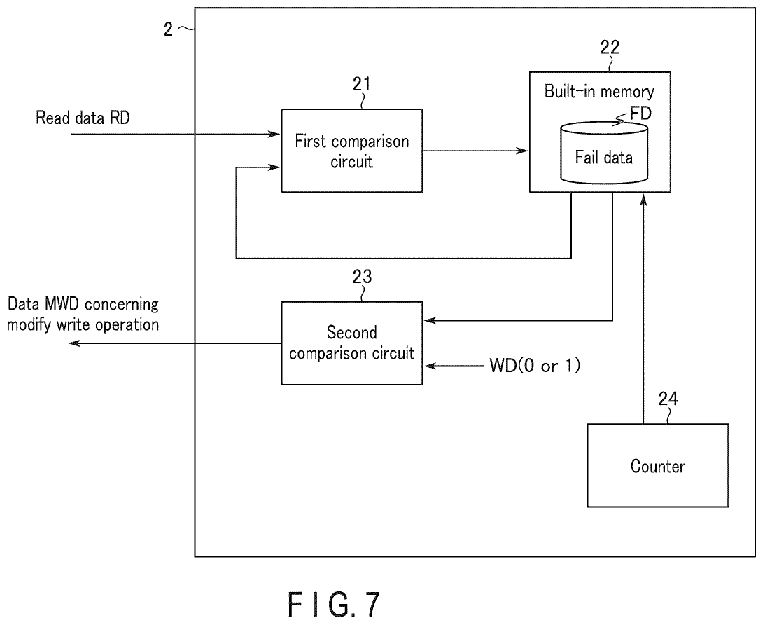

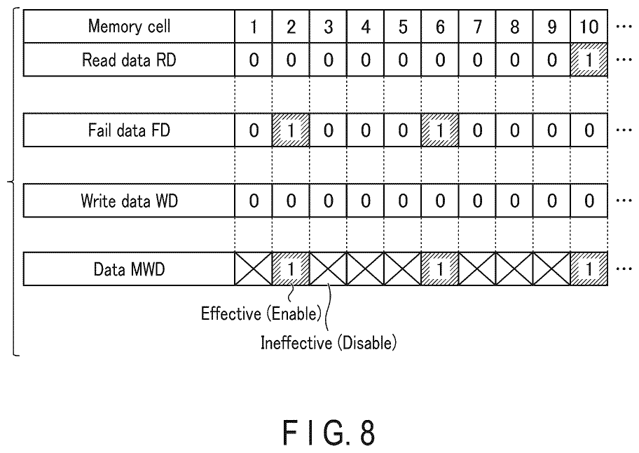

An example of the arrangement of the memory controller 2 will be further described next with reference to FIGS. 7 and 8. FIG. 7 is a block diagram for explaining the arrangement of the memory controller of the memory system according to the embodiment. The following will exemplify some of the components of the memory controller 2 which are used for seasoning processing in the memory system 3. FIG. 8 is a view for explaining various types of data in the memory system according to the embodiment.

The memory controller 2 includes the first comparison circuit 21, the built-in memory 22, the second comparison circuit 23, and the counter 24.

The first comparison circuit 21 receives read data RD from the storage device 1. As shown in FIG. 8, the read data RD stores the data read from each memory cell MC in one of a plurality of seasoning read operations in seasoning processing. In addition, the first comparison circuit 21 receives fail data FD from the built-in memory 22. The fail data FD stores whether each memory cell MC has failed in a seasoning read operation executed before the one seasoning read operation. The first comparison circuit 21 compares the received read data RD with the received fail data FD. The first comparison circuit 21 then updates the fail data FD in the built-in memory 22 based on the comparison result. The comparison between the read data RD and the fail data FD and the updating of the fail data FD will be described later.

The fail data FD will be supplementarily described. As described above, in forming processing and seasoning processing, the storage device 1 applies a write current to the memory cell MC. This enables each memory cell MC to be set in a state in which data “0” or data “1” is written in accordance with the write current. In seasoning processing, a write current for the same data is applied to all the memory cells MC. That each memory cell MC has failed means that data different from the above data is read in a seasoning read operation. In addition, that each memory cell MC has passed means that the same data as the above data is read in a seasoning read operation. In the following case, in seasoning processing, a write current for data “0” is applied to all the memory cells MC. As shown in FIG. 8, the fail data FD stores data “1” as data corresponding to the memory cell MC that has failed once or more in a seasoning read operation that has already been executed. In addition, the fail data FD stores, for example, data “0” as data corresponding to the memory cell MC that has passed all the seasoning read operations that have already been executed.

The second comparison circuit 23 receives the fail data FD from the built-in memory 22. The second comparison circuit 23 compares the received fail data FD with write data WD. The write data WD is data corresponding to the write current applied to each memory cell MC in seasoning processing. This embodiment exemplifies the case where a write current corresponding to data “0” is applied as described above. The second comparison circuit 23 generates data MWD associated with a modify write operation based on the result of the comparison between the fail data FD and the write data WD. The data MWD stores whether a modify write operation is further required for each memory cell MC. As shown in FIG. 8, the data MWD stores that a modify write operation is effective (Enable) with respect to the memory cell MC requiring a further modify write operation. In addition, the data MWD stores that a modify write operation is ineffective (Disable) with respect to the memory cell MC that does not require any further modify write operation. Referring to FIG. 8, data indicating that a modify write operation is effective is written as “1”. In addition, data indicating that a modify write operation is ineffective is written as “x”. The comparison between the fail data FD and the write data WD and the generation of the data MWD will be described later. The second comparison circuit 23 transmits the data MWD described above to the input/output circuit 17 of the storage device 1. This enables the storage device 1 to selectively execute a modify write operation with respect to the memory cell MC further requiring a modify write operation. Accordingly, a modify write operation is also called selective seasoning processing.

The counter 24 counts the number of times a seasoning read operation is executed in seasoning processing, the number of times a modify write operation is executed, and the number of times a combination of a plurality of seasoning read operations and a plurality of modify write operations is executed. The counter 24 controls the transmission of the fail data FD from the built-in memory 22 to the first comparison circuit 21 and the transmission of the fail data FD from the built-in memory 22 to the second comparison circuit 23 based on the counts. For example, the memory controller 2 may include a switch that couples the built-in memory 22 and the first comparison circuit 21 to each other and a switch that couples the built-in memory 22 and the second comparison circuit 23 to each other. In this case, for example, the counter 24 performs control to set these switches in an ON state or an OFF state.

### 1.2 Seasoning Processing

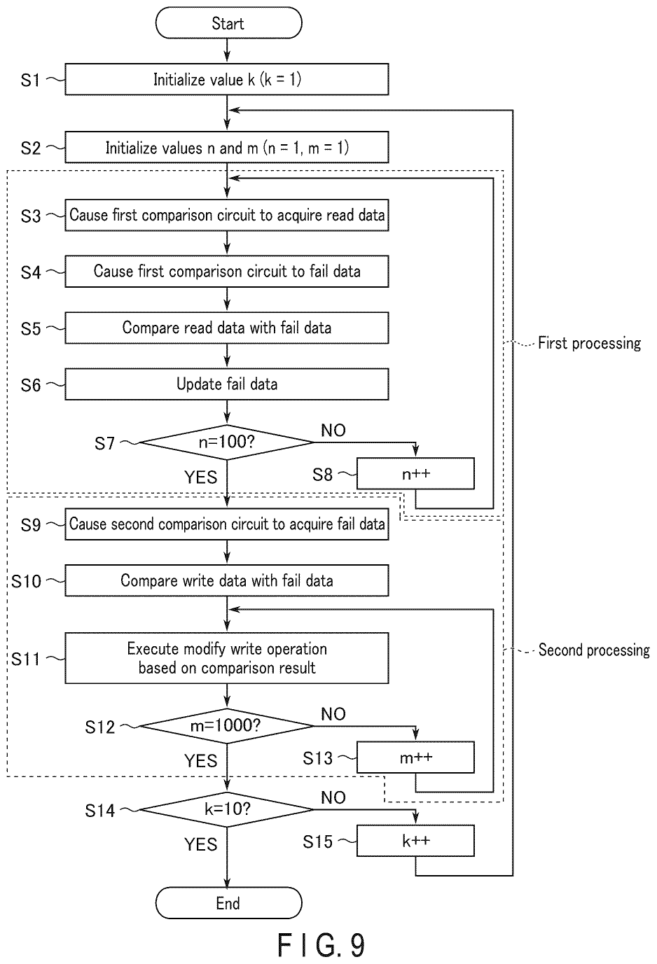

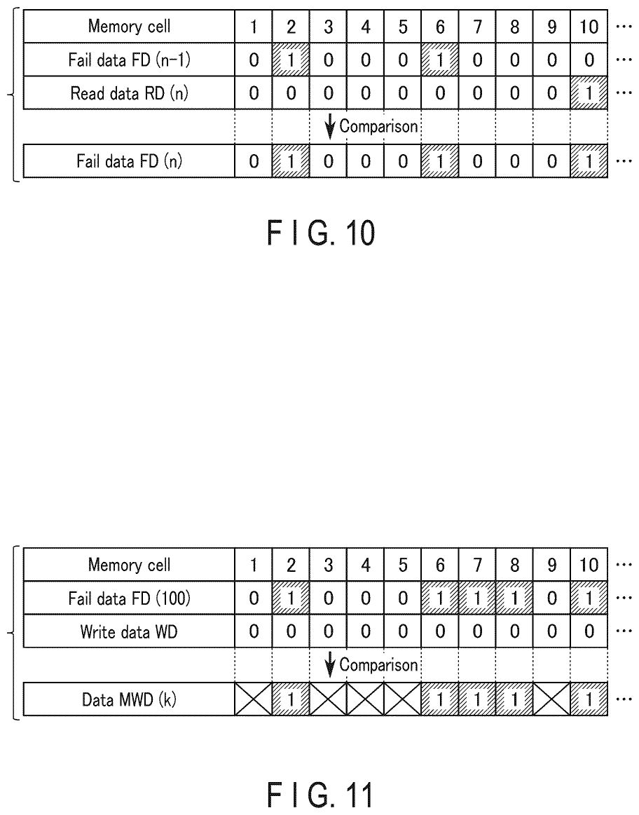

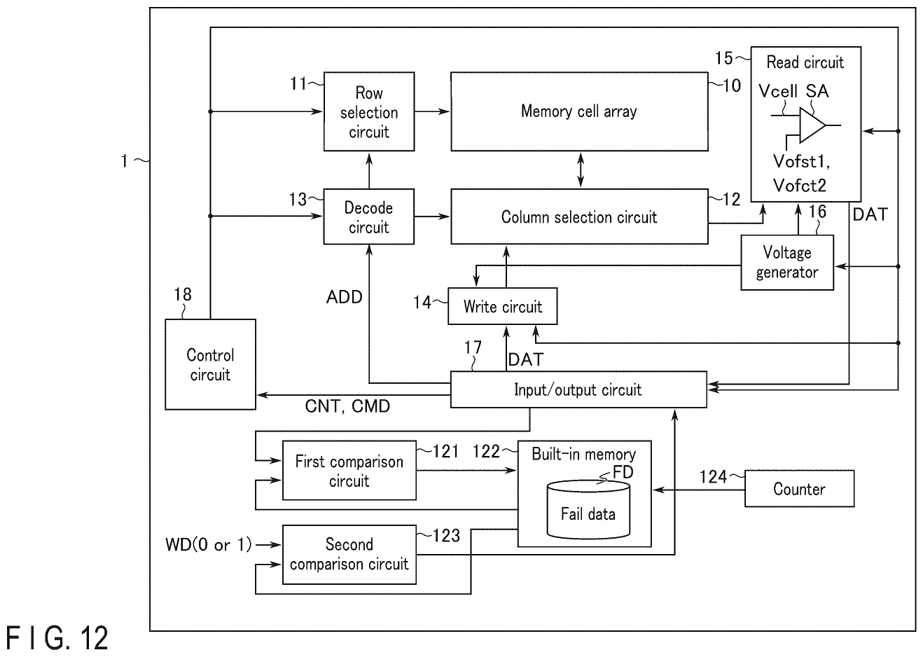

An example of seasoning processing using the memory system 3 according to the embodiment will be described with reference to FIGS. 9, 10, and 11. FIG. 9 is a flowchart for explaining seasoning processing in the memory system according to the embodiment. FIG. 10 is a view for explaining the updating of fail data in seasoning processing in the memory system according to the embodiment. FIG. 11 is a view for explaining data used in a modify write operation in seasoning processing in the memory system according to the embodiment.

In the processing in step S1, the counter 24 of the memory controller 2 initializes a value k (k=1). The value k is a natural number. The process then advances to step S2.

In the processing in step S2, the counter 24 of the memory controller 2 initializes the values n and m (n=1 and m=1). The values n and m are natural numbers. The process then advances to step S3.

The first comparison circuit 21 of the memory controller 2 acquires the read data RD by the nth seasoning read operation (S3). More specifically, the storage device 1 executes, for example, the nth seasoning read operation with respect to each memory cell MC. The first comparison circuit 21 then acquires the read data RD by the seasoning read operation from the storage device 1. In the following description, the nth read data RD is also simply called read data RD(n). The process then advances to step S4.

The processing in step S3 will be supplementarily described. In the description of the processing in step S3, data written by forming processing is defined as the first data. The following will exemplify a case where if the read voltage Vcell1 in a normal read operation is equal to or higher than the reference voltage Vofst1, the corresponding data is determined as the first data, whereas if the read voltage Vcell1 is less than the reference voltage Vofst1, the corresponding data is determined as the second data different from the first data. In a seasoning read operation in the processing in step S3, each sense amplifier SA uses the reference voltage Vofst2 different from the reference voltage Vofst1 as described above. The reference voltage Vofst2 is set to a voltage at which the sense amplifier SA can easily read erroneous data of the data written by forming processing and a modify write operation (to be described later). That is, the reference voltage Vofst2 is set to, for example, a voltage higher than the reference voltage Vofst1. This makes it easy to determine that the memory cell MC has failed in a seasoning read operation. Note that the reference voltage Vofst2 may be set to a voltage lower than the reference voltage Vofst1 in accordance with the data determination method or the like as long as the voltage is set to a voltage at which the sense amplifier SA can easily read erroneous data of the data written by the application of a write voltage in forming processing.

The first comparison circuit 21 acquires the fail data FD from the built-in memory 22 (S4). The fail data FD acquired by the first comparison circuit 21 in step S4 is the (n−1)th fail data FD based on the seasoning read operation executed before the nth seasoning read operation. In the following description, the nth fail data FD is also simply called fail data FD(n). The process then advances to step S5.

The first comparison circuit 21 compares read data RD(n) with fail data FD(n−1) concerning each memory cell MC (S5). The process then advances to step S6.

The processing in step S5 will be supplementarily described with reference to FIG. 10. The first comparison circuit 21 performs, for example, the logical OR operation (OR operation) between the read data RD(n) and the fail data FD(n−1) with respect to each memory cell MC. The first comparison circuit 21 then generates the fail data FD(n) by using the result of the logical OR operation. In the above manner, the fail data FD(n) stores data “1” as data corresponding to the memory cell MC that has failed once or more by the time of the nth seasoning read operation. In addition, the fail data FD(n) stores data “0” as data corresponding to the memory cell MC that has passed all the seasoning read operations from the first operation to the nth operation.

The first comparison circuit 21 updates the fail data FD(n−1) in the built-in memory 22 into the fail data FD(n) based on the result of the processing in step S5 (S6). The process then advances to step S7.

The counter 24 determines whether the value n is 100 (S7). If the value n is 100 (S7: YES), the process advances to step S9. If the value n is not 100 (S7: NO), the value n is less than 100. In this case, the process advances to step S8.

In step S8, the counter 24 increments (n++). The processing in step S3 is then executed again.

The second comparison circuit 23 acquires the fail data FD(n) from the built-in memory 22 (S9). The process then advances to step S10.

The fail data FD is updated based on the comparison between each read data RD and the fail data FD until 100 seasoning read operations are executed. In the following description, the processing from step S3 to step S8 will be also referred to as the first processing.

The second comparison circuit 23 compares the write data WD with the fail data FD(n) with respect to each memory cell MC (S10). The second comparison circuit 23 transmits the data MWD based on the comparison result to the storage device 1. The process then advances to step S11.

The processing in step S10 will be supplementarily described with reference to FIG. 11. The second comparison circuit 23 generates the data MWD concerning a modify write operation by using the operation result between the write data WD and the fail data FD(n). The data MWD stores data “1” (Enable) as data corresponding to the memory cell MC that has failed once or more by all the time seasoning read operations are executed from the first operation to the 100th operation. In addition, the data MWD stores data (“x” (Disable)) indicating that no modify write operation is executed with respect to the memory cell MC that has passed all the seasoning read operations from the first operation to the 100th operation. The second comparison circuit 23 performs logical OR operation (OR operation) between the write data WD and the fail data FD(n) with respect to each memory cell MC. Note that the second comparison circuit 23 can execute a different operation instead of a logical OR operation depending on the data stored by the write data WD and the fail data FD. In addition, in the following description, the data MWD concerning a modify write operation concerning the value k will be also referred to as data MWD(k).

The storage device 1 executes the mth modify write operation concerning the value k by using the data MWD(k) transmitted from the second comparison circuit 23 (S11). In a modify write operation, the storage device 1 increases the voltage between the terminals of the switching element SEL to make a write current flow in the memory cell MC corresponding to the data MWD(k) indicating that the modify write operation is effective. In addition, the storage device 1 executes no write operation with respect to the memory cell MC corresponding to the data MWD(k) indicating that the modify write operation is ineffective. The process then advances to step S12.

The counter 24 determines whether the value m is 1,000 (S12). If the value m is 1,000 (S12: YES), the process advances to step S14. If the value m is not 1,000 (S12: NO), the value m is less than 1,000. In this case, the process advances to step S13.

In step S13, the counter 24 increments (m++). The processing in step S11 is then executed again.

In the above manner, 1,000 modify write operations are executed based on the comparison between the write data WD and fail data FD(100). In the following description, the processing from step S9 to step S13 will also be referred to as the second processing.

The counter 24 determines whether the value k is 10 (S14). If the value k is 10 (S14: YES), the processing is terminated. If the value k is not 10 (S14: NO), the value k is less than 10. In this case, the process advances to step S15.

In step S15, the counter 24 increments (k++). The processing in step S2 is then executed again.

In the above manner, a combination of the first processing and the second processing is executed 10 times.

With the above operation, the seasoning processing is terminated. As described above, in seasoning processing, for example, a combination of the first processing of updating the fail data FD 100 times and the second processing of executing 1,000 modify write operations with respect to the target memory cell MC is repeatedly executed 10 times.

Note that the numbers of times of updating the fail data FD in the first processing, performing a modify write operation in the second processing, and performing a combination of the first processing and the second processing each are not limited to the above example as long as it is plural.

1.3 Effects according to Embodiment

According to the embodiment, the characteristics of the storage device can be improved. The effects of the embodiment will be described below.

The memory system 3 according to the embodiment includes the storage device 1 and the memory controller 2. The storage device 1 includes the word lines WL, the bit lines BL, the memory cells MC, the write circuit 14, and the read circuit 15. Each memory cell MC includes the magnetoresistance effect element MTJ and the switching element SEL electrically coupled to the word line WL and the bit line BL and also coupled in series. The memory system 3 executes seasoning processing including the first processing and the second processing. In the first processing, the read circuit 15 executes 100 read operations. In addition, in the first processing, the memory controller 2 generates the fail data FD(100) based on the result of a plurality of read operations. The fail data FD(100) stores whether data read has failed once or more in 100 read operations in each memory cell MC. In the second processing, the write circuit 14 executes 1,000 modify write operations (selective seasoning processing) with respect to the memory cell MC in which data read has failed once or more based on the fail data FD(100). With the above arrangement, the characteristics of the storage device 1 can be improved.

The above effects will be supplementarily described. The storage device is preferably configured such that the characteristics of the switching elements and the characteristics of read voltages in all the memory cells are almost the same. Accordingly, a comparative embodiment may be conceivable, which is configured to execute the same number of times of modify write operations with respect to all the memory cells in seasoning processing. However, in the comparative embodiment, even if the same number of times of modify write operations are executed, the characteristics of the switching elements and the characteristics of read voltages after seasoning processing sometimes vary due to the variation in the characteristics of the memory cells. In addition, if, for example, the number of times of modify write operations is increased with reference to a memory cell in which the drop in read voltage due to the repetition of a modify write operation is slow, read voltage Vcell in some memory cells sometimes excessively drops. This sometimes causes breakdown of a memory cell, such as keeping the switching element always in an ON state.

According to the embodiment, the memory system 3 executes selective seasoning processing with respect to only the memory cell MC in which data read has failed in 100 seasoning read operations. This makes it possible to change the characteristics of the switching element and the characteristics of the read voltage Vcell in accordance with the variation in the characteristics of the memory cell. Accordingly, it is possible to improve the uniformity of the characteristics of the switching element and the characteristics of the read voltage Vcell.

In addition, according to the embodiment, the sense amplifier SA uses the reference voltage Vofst2 instead of the reference voltage Vofst1 used in a read operation in a seasoning read operation. The reference voltage Vofst2 is set to a voltage at which the sense amplifier SA easily reads erroneous data of the data written by forming processing and a modify write operation. This makes it possible to promote seasoning processing as compared with the case using the reference voltage Vofst1 in a seasoning read operation.

### 2. Modification

The above embodiment can be variously modified.

The above embodiment has exemplified the case where the memory controller updates the fail data FD and generates the data MWD. However, the present invention is not limited to this. The storage device may update the fail data FD and generate the data MWD.

The operation in the modification can be made similar to that in the embodiment except that the storage device updates the fail data FD and generates the data MWD. Accordingly, a description of the operation is omitted, and the arrangement of the storage device according to the modification will be described below.

An example of the arrangement of the storage device according to the modification will be described with reference to FIG. 12. FIG. 12 is a block diagram for explaining the arrangement of the storage device according to the modification.

The storage device 1 according to the modification further includes a first comparison circuit 121, a built-in memory 122, a second comparison circuit 123, and a counter 124.

The arrangements of the first comparison circuit 121, the built-in memory 122, the second comparison circuit 123, and the counter 124 are similar to those of the comparison circuit, the built-in memory, the comparison circuit, and the counter except that they are included in the memory controller.

Even the modification can obtain similar effects to the embodiment.

### 3 Others

While certain embodiments have been described, these embodiments have been presented by way of example only, and are not intended to limit the scope of the inventions. Indeed, the novel embodiments described herein may be embodied in a variety of other forms. Furthermore, various omissions, substitutions, and changes in the form of the embodiments may be made without departing from the spirit of the inventions. The accompanying claims and their equivalents are intended to cover such forms or modifications as would fall within the scope and spirit of the inventions.

What is claimed is:

1. A memory system comprising:
a storage device including a first interconnect and a second interconnect, a plurality of memory cells each having a variable resistance element and a switching element electrically coupled to the first interconnect and the second interconnect and coupled in series, a write circuit configured to write data in the plurality of memory cells, and a read circuit configured to read data written in the plurality of memory cells; and
an external device,
wherein the memory system is configured to execute seasoning processing including first processing and second processing,
in the first processing, the read circuit executes a plurality of seasoning read operations each configured to read data from the plurality of memory cells, and the external device generates first fail data storing whether in each of the plurality of memory cells, data read has failed not less than once in the plurality of seasoning read operations, and
in the second processing, the write circuit executes selective seasoning processing a plurality of times with respect to a target memory cell, of the plurality of memory cells, which is determined based on the first fail data.

2. The system according to claim 1, wherein the external device comprises a first circuit,
in the first processing, the first circuit updates second fail data, in each of the plurality of memory cells every time each of the plurality of seasoning read operations is executed, based on comparison between data in the seasoning read operation and the second fail data storing whether data read has failed not less than once before the seasoning read operation of the plurality of seasoning read operations, and
the second fail data updated by using data in a last seasoning read operation of the plurality of seasoning read operations is set as the first fail data.

3. The system according to claim 2, wherein the external device further comprises a second circuit, and
in the second processing, the second circuit determines the target memory cell for each of the plurality of memory cells based on comparison between the first data and the first fail data.

4. The system according to claim 3, wherein the external device further comprises a built-in memory, and
the built-in memory stores the second fail data.

5. The system according to claim 4, wherein the external device comprises a counter, and
the counter counts the number of times a seasoning read operation is executed in the first processing and the number of times selective seasoning processing is executed in the second processing, and
controls the built-in memory so as to transmit the second fail data to the first circuit based on a result of the counting and transmit the first fail data to the second circuit.

6. The system according to claim 1, wherein a combination of the first processing and the second processing is executed a plurality of times.

7. The system according to claim 1, wherein in the selective seasoning processing, the write circuit applies a first write current to the memory cell.

8. The system according to claim 1, wherein in each of the plurality of seasoning read operations,
the read circuit reads data from the memory cell based on comparison between a voltage of the first interconnect when a first read voltage is applied to each of the plurality of memory cells and a first reference voltage and
in a read operation after the seasoning processing,
reads data from the memory cell based on comparison between a voltage of the first interconnect when a first read voltage is applied to each of the plurality of memory cells and a second reference voltage different from the first reference voltage.

9. A storage device comprising:
a first interconnect and a second interconnect;
a plurality of memory cells each having a variable resistance element and a switching element electrically coupled to the first interconnect and the second interconnect and coupled in series;
a write circuit configured to write data in the plurality of memory cells;
a read circuit configured to read data written in the plurality of memory cells; and
a first circuit,
wherein the storage device is configured to execute seasoning processing including first processing and second processing,
in the first processing, the read circuit executes a plurality of seasoning read operations each configured to read data from the plurality of memory cells, and the first circuit generates first fail data storing whether in each of the plurality of memory cells, data read has failed not less than once in the plurality of seasoning read operations, and
in the second processing, the write circuit executes selective seasoning processing a plurality of times with respect to a target memory cell, of the plurality of memory cells, which is determined based on the first fail data.

10. The device according to claim 9, wherein in the first processing,
the first circuit updates second fail data, in each of the plurality of memory cells every time each of the plurality of seasoning read operations is executed, based on comparison between data in the seasoning read operation and the second fail data storing whether data read has failed not less than once before the seasoning read operation of the plurality of seasoning read operations, and
the second fail data updated by using data in a last seasoning read operation of the plurality of seasoning read operations is set as the first fail data.

11. The device according to claim 10, further comprising a second circuit,
wherein in the second processing, the second circuit determines the target memory cell for each of the plurality of memory cells based on comparison between the first data and the first fail data.

12. The device according to claim 11, further comprising a built-in memory,
wherein the built-in memory stores the second fail data.

13. The device according to claim 12, further comprising a counter,
wherein the counter counts the number of times a seasoning read operation is executed in the first processing and the number of times selective seasoning processing is executed in the second processing, and
controls the built-in memory so as to transmit the second fail data to the first circuit based on a result of the counting and transmit the first fail data to the second circuit.

14. The device according to claim 9, wherein a combination of the first processing and the second processing is executed a plurality of times.

15. The device according to claim 9, wherein in the selective seasoning processing, the write circuit applies a first write current to the memory cell.

16. The device according to claim 9, wherein in each of the plurality of seasoning read operations,
the read circuit reads data from the memory cell based on comparison between a voltage of the first interconnect when a first read voltage is applied to each of the plurality of memory cells and a first reference voltage and
in a read operation after the seasoning processing,
reads data from the memory cell based on comparison between a voltage of the first interconnect when a first read current is applied to each of the plurality of memory cells and a second reference voltage different from the first reference voltage.
